(19) United States
(12) Patent Application Publication
(10) Pub. No.: US 2010/0136313 A1
(43) Pub. Date: Jun. 3, 2010

(54) PROCESS FOR FORMING HIGH RESISTIVITY THIN METALLIC FILM

(75) Inventors: Akira Shimizu, Sagamihara (JP); Akiko Kobayashi, Tokyo (JP); Suvi Haukka, Helsinki (FI)

Correspondence Address: KNOBBE MARTENS OLSON & BEAR LLP, 2040 MAIN STREET, FOURTEENTH FLOOR, IRVINE, CA, 92614, US

(73) Assignee: ASM JAPAN K.K., Tama (JP)

(21) Appl. No.: 12/326,000

(22) Filed: Dec. 1, 2008

(51) Int. Cl. C23C 16/34; B32B 9/00; C01B 33/00

(52) U.S. Cl. 428/220; 427/101; 423/324

(57) ABSTRACT

A process for forming metallic nitride film by atomic layer deposition (ALD), which comprises steps for feeding into a reaction space vapor phase alternated pulses of metal source material and silicon source material in a plurality of cycles, and feeding into the reaction space vapor phase pulses of nitrogen source material. wherein a nitrogen source pulse is fed intermittently in selected cycles such that a ratio of nitrogen source pulses to silicon source pulses is less than 1:1 and a ratio of nitrogen source pulses to metal source pulses is less than 1:1, the ratio selected to produce the thin film with a resistivity between 1,000 μΩcm and 15,000 μΩcm.

### BACKGROUND OF THE INVENTION

1. Field of the Invention

The present invention relates to a process for forming thin metal film, more particularly, the present invention relates to a process for forming metal nitride thin film by atomic layer deposition (ALD), controlling the resistivity thereof.

2. Description of the Related Art

Tantalum Nitride (TaN) thin films have been used as barrier films in metallization for integrated circuits. Additionally, tantalum silicon nitride compounds (TaSiN) have been described as useful for transistor gate electrode applications. For example, U.S. Pat. No. 6,518,106 describes that gate electrode and electrode work function can be tuned by the concentration of nitrogen in tantalum silicon nitride (TaSiN).

The resistivity is one of the critical material properties to control for various layers used in making semiconductor devices. Normally the resistivity is mostly determined by the material itself. A thin film resistor is useful for very large scale or ultra large scale integration whose circuitry requires a high sheet resistivity. Polycrystalline silicon and thin metal films are useful for making resistors. However, the resistivity of polycrystalline silicon has a high sensitivity to temperature, which is not suitable for analog circuits, and the resistivity of the resistors using silicon tends to be relatively low. The resistivity of polycrystalline silicon is typically in the range of 100˜1,000 μΩ·cm. Accordingly, methods for forming layers for resistors with higher resistivity are desirable.

Another issue is controllability and accuracy of the sheet resistance (resistivity/film thickness). For barrier films or electrodes, it would be very useful if the resistivity was subject to fine control.

With PVD (physical vapor deposition), the resistivity can be controlled by changing concentration of nitrogen gas in the chamber during sputtering of Ta target. (N. Cuong and et al., Journal of electrochemical society, 153, 2 (2006) G164). Such PVD techniques offer good control over resistivity over particular ranges of composition and are also relatively economical. However, this process has been found to be impractical for conductive materials of very high resistivity.

Based on its general properties, atomic layer deposition (ALD) is a potentially attractive alternative. ALD, originally known as atomic layer epitaxy (ALE), is advanced form of vapor deposition that facilitates the formation of thin films monolayer by monolayer. ALD processes are based on sequential self-saturated surface reactions. Examples of these processes are described in detail in U.S. Pat. Nos. 4,058,430 and 5,711,811. The described deposition processes benefit from using inert carrier and purging gases to reduce the interval between pulses of reactants in order to increase deposition speed.

According to the principles of ALD, the source chemicals (or precursors) are separated from each other, e.g. by inert gases (purging) between reactant pulses, which substantially prevents gas-phase reactions between gaseous reactants, thereby facilitating the film growth by the above-mentioned self-saturating surface reactions. Advantageously, ALD requires neither strict temperature control of the substrates nor precise dosage control of source chemicals, enabling wide process windows without sacrificing uniformity. Surplus chemicals and reaction by-products are removed from the reaction chamber before the next reactive chemical pulse is introduced into the chamber. Undesired gaseous molecules are effectively expelled from the reaction chamber by keeping the gas flow speeds high with the help of an inert purging gas. The purging gas pushes the extra molecules towards the vacuum pump used for maintaining a suitable pressure in the reaction chamber. Advantageously, ALD provides an excellent and automatic self-limited mechanism for controlling film growth, leading to outstanding conformality.

While ALD is commonly suggested for use with various layers of a critical nature in integrated circuits, such as ultra thin barrier layers or gate dielectric layers, no satisfactory process is known for producing thin metal films having high resistivity by the atomic layer deposition technique.

### SUMMARY OF THE INVENTION

In one aspect, a method is disclosed for forming a metal nitride thin film by atomic layer deposition (ALD). The method includes feeding into a reaction space vapor phase alternated pulses of metal source material and silicon source material in a plurality of cycles. Vapor phase pulses of nitrogen source material are fed into the reaction space. The nitrogen source pulses are fed intermittently in selected cycles after a sequence of a metal source material pulse and a silicon source material pulse, such that a ratio of nitrogen source pulses to silicon source pulses is less than 1:1 and a ratio of nitrogen source pulses to metal source pulses is less than 1:1. The deposited metal nitride thin film has a resistivity between 1,000 μΩcm and 15,000 μΩcm.

In another aspect, an atomic layer deposition process is provided for depositing a conductive TaSiN film. The process includes a plurality of cycles that include supplying a pulse of TaF₅ to a reaction space housing a substrate, and supplying a pulse of trisilylamine (TSA) to the reaction space. The process also includes, in selected cycles, supplying a pulse of NH₃ between supplying the pulse of TSA and supplying the pulse of TaF₅. The pulse of NH₃ is supplied intermittently in fewer than all of the ALD cycles in a pulse ratio selected to tune resistivity of the conductive TaSiN film.

In one embodiment, a conductive metal nitride thin film is provided with a resistivity between 1,000 μΩcm and 15,000 μΩcm. The thickness non-uniformity (NU) across the substrate can be less than 1%, and resistivity non-uniformity (Rs NU) can also be less than 1%. For resistor applications, the minimum thickness should be 50 nm; however, formation by ALD, enables reaching such uniformity targets for much thinner layers than otherwise possible, which is better for productivity,

### BRIEF DESCRIPTION OF THE DRAWINGS

These and further aspects of the invention will be readily apparent to those skilled in the art from the following description and the attached drawings, wherein:

FIG. 1 schematically illustrates a film forming apparatus including some peripheral components.

FIG. 2 shows a sequence chart of material feeding pulses, in accordance with a preferred embodiment to form TaSiN thin film with TaF₅, TSA, and NH₃

FIG. 3 shows an evaluation result obtained from TaSiN thin films formed by changing the feeding pulse ratio of the nitrogen over TaSiN.

FIG. 4 shows a flow chart of the general forming process.

FIG. 5 shows a flow chart of TaSiN thin film forming process.

### DETAILED DESCRIPTION OF THE PREFERRED EMBODIMENT

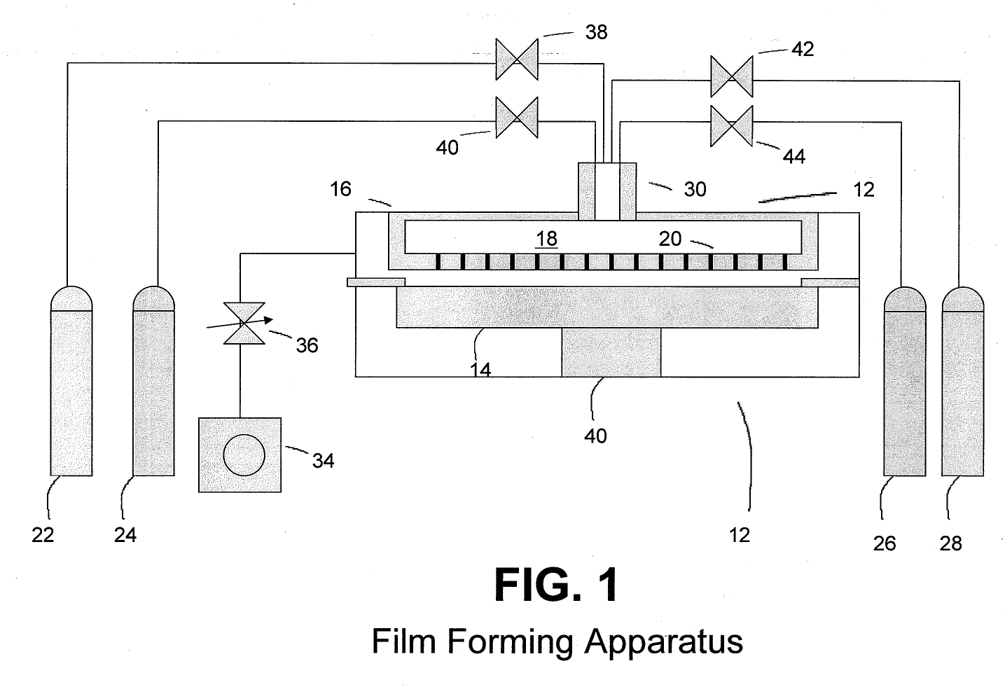

As shown in FIG. 1, ALD apparatus according to one embodiment comprises a reaction chamber 12 equipped with a susceptor 14 for supporting a substrate within under a showerhead 16 or other gas inlet structure. The susceptor 14 can be heated in a variety of manners, such as internal resistive heating coils. The showerhead 16 contains a cavity known as a showerhead plenum 18 and showerhead plate 20, which has openings for supplying gases to the substrate. Process gas sources communicate with the inlet structure or showerhead 16. In the illustrated embodiment, the gas sources include a metal precursor source 22, a silicon precursor source 24, a nitrogen precursor source 26 and a source of inert or purge gas 28. The process gas sources 22-28 communicate with the showerhead plenum 18 through an inlet 30 and the showerhead plate 20 provides some backpressure to spread the gases across the plenum 18 and feed gas downward uniformly through multiple holes. A pedestal 32 supports the susceptor 14, which in turn supports a substrate directly beneath the showerhead plate 20. The pedestal 32 moves the susceptor 14 down for loading/unloading substrates (e.g., semiconductor wafers) from the side, and moves the susceptor/substrate combination up to close the reaction chamber off. In the illustrated closed position, a reaction space is defined between the showerhead plate 20 and the susceptor 14.

Also shown are a vacuum pump 34 and an accompanying valve 36 equipped to control the process pressure. Valves 38-44 control the supply of precursor pulses of precursors and purge gas from the gas sources 22-28, respectively. A controller (not shown), typically including a processor and a memory, is programmed to control the equipment to conduct the processes described below.

The skilled artisan will appreciate that the apparatus is not limited to the illustrated configuration. Methods described hereinbelow are applicable to other types of ALD equipment as well, including, but not limited to, batch reactors (for simultaneously processing multiple substrates), horizontal or cross-flow designs, or fill and soak (rather than flow-through) designs. The skilled artisan will readily find alternative configurations based on the principals disclosed in here without departing from the spirit and scope of the invention.

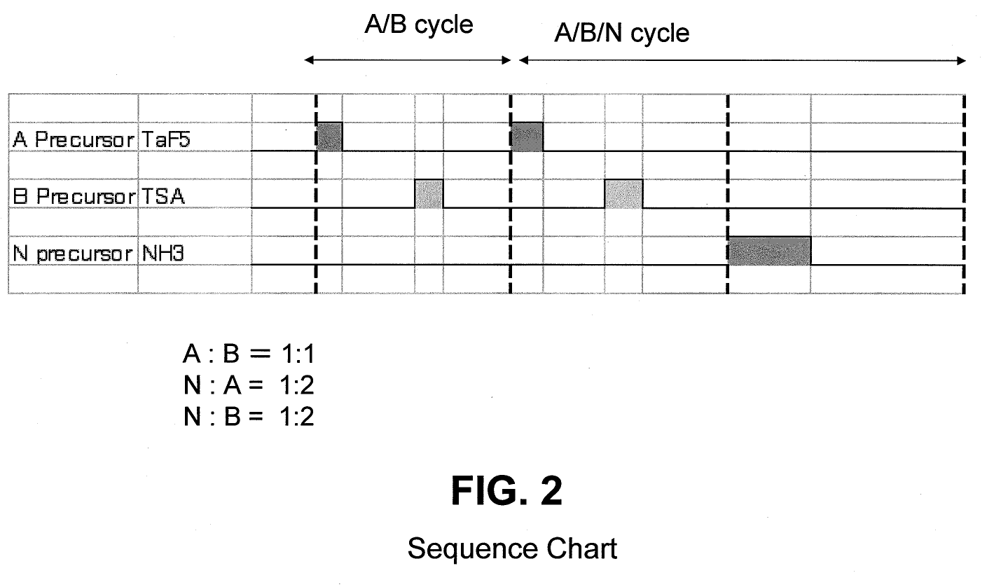

FIG. 2 illustrates an ALD reactant pulse sequence in accordance with one embodiment. In the illustrated process, the metal source material or precursor comprises a metal halide, particularly tantalum fluoride (TaF₅) or niobium fluoride (NbF₅), and is referred to as “precursor A.” Other suitable metal precursors for the process include, but are not limited to, are tantalum chloride (TaCl₅), pentakisdimethylaminotantalum (PDMAT), tertiaryamylimidot(dimethylamido) tantalum (Ta[N(CH₃)₂]₅), t-butylamino(diethylamino)tantalum (TBTDET), tris((diethylamido)(tert-butylimido)tantalum ((CH₃)₃CN—Ta[N(C₂H₅)₂]₃), titanium tetrachloride (TiCl₄), tetrakis(dimethylamino)titanium (TDMAT: Ti{N(CH₃)₂}₄_{_{—}}), terakis(diethylamido)titanium (TDEAT: Ti{N(C₂H₅)₂}), terakis(dimethylamido)titanium TDMAT, and tungsten hexafluoride (WF₆). The illustrated silicon source material or precursor is trisilylamine or TSA and is referred to as “precursor B.” Other suitable silicon precursors for the process include, but are not limited to, are silane (SiH₄), silicon chloride (SiCl₄) tetramethyldisilazane (TMDS: [CH₃]₂HSiNHSiH[CH₃]₂) tris(dimethylamino)silane (TDMAS: SiH[N(CH₃)₂]₂), bis(diethylamino)silane (BDEAS: SiH₂[N(C₂H₅)₂]₂, Si₂H₆). The illustrated nitrogen source material or precursor is ammonia (NH₃) and is referred to as “precursor N.” Other suitable nitrogen precursors for the process include, but are not limited to, are nitrogen (N₂), hydrazine (H₂NNH₂), and/or hydrogen plasma, radicals or atoms.

For purposes of illustration, FIG. 2 shows a material feeding sequence with a ratio of nitrogen source pulses to silicon/metal source pulses of 1:2. As shown, a first pulse A, which is the metal source material, is fed to saturatively form a first self-terminated monolayer. After a first purge step, represented by the gap between A and B pulses, a first pulse B, which is the silicon source material, is fed, followed by a second purge step represented by the gap prior to the next precursor pulse, which conclude one A/B cycle (metal/silicon). A second pulse A is fed, followed by a second pulse B, separated by a third purge step. After a fourth purge step, a first pulse N, representing the nitrogen source material, is fed followed by a fifth purge step, which concludes a second cycle, in this case a A/B/N cycle (metal/silicon/nitrogen). Then the above sequence can be repeated with the desired ratio repeated until a desired thickness is obtained, such as a thickness greater than 50 nm for a resistor application. In this example, a nitrogen source pulse is fed in selected cycles such that a ratio of nitrogen source pulses to silicon source pulses is 1:2, and the ratio of nitrogen source pulses to metal source pulses is 1:2. In other words, there is a 50% ratio of the frequency of nitrogen pulses to metal/silicon pulses, or more specifically a 50% ratio of NH₃ pulses to TaF₅/TSA pulses.

For the sequence and precursors illustrated for the embodiment of FIG. 2, each cycle includes a metal source pulse and a silicon source pulse. The illustrated metal source pulse (TaF₅) adsorbs without thermal decomposition to leave no more than about a monolayer of tantalum fluoride species. The subsequent silicon source pulse (TSA) reacts with the adsorbed monolayer to form a monolayer of metal nitride, and some silicon may also be left in the film. The composition of the components in a 600 μΩcm film would be Ta:Si:N=38:18:27, and for a 3000 μΩcm film would be Ta:Si:N=26:18:38. Thus, the result of these pulses alone, if repeated without nitrogen source pulses, is represented by reaction formula below, where TSA is represented by its chemical formula (SiH₃)₃N:

TaF₅+(SiH₃)₃N→TaN(s)+SiFₓ(g)

Suitable reaction conditions for the foregoing ALD sequence is include a substrate temperature of 250° C. and reaction space pressure of 200 Pa. As the purge gas, any inert gas such as argon (Ar) or helium (He) can be used.

In selected cycles fewer than all of the cycles (e.g., from 10% to 90% of the cycles), a nitrogen source pulse is provided. In the illustrated embodiment, in each cycle where the nitrogen source pulse is provided, it is desirably provided after both metal and silicon source pulses in that cycle. This feeding sequence has been found significant. For example, a [TaF₅→NH₃] sequence with no intervening TSA would form Ta₃N₅, which is an insulating material. A [TSA→NH₃] sequence, with no prior adsorbed TaF₅ pulse would form SiN, which is also insulating material. The illustrated [TaF₅→TSA→NH₃] sequence, with nitrogen source NH₃ pulse fed following a silicon source TSA pulse, and prior to the next metal source TaF₅ pulse, the resistivity can be controlled to maintain conductivity, and modulate resistivity by the ratio of nitrogen source pulses relative to the silicon source and metal source pulses.

Thus, the above sequence and material combination with ALD method offer good control of nitrogen concentration, and as a result, the resistivity is controlled more accurately than the other method. At the same time, ALD affords high uniformity of thickness and composition, allowing for highly uniform sheet resistance. Desirably, the non-uniformity for sheet resistance across the film is within 1%.

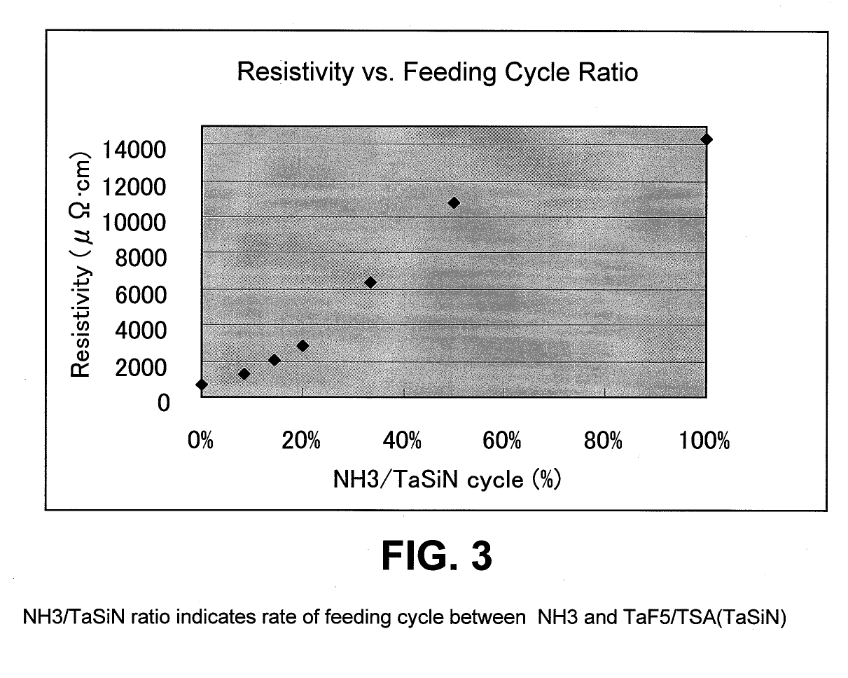

FIG. 3 shows the results of experimentation and indicates that the process described herein offers a strong correlation between the resistivity and the pulse ratio, which leads to accurate control or modulation of resistivity. In the figure, NH₃/TaSiN cycle (%) refers to the proportion or ratio of the number of feeding pulses of NH₃ relative to the number of feeding pulses of TaF₅/TSA. At 0% ratio of NH₃/TaSiN (no NH₃ is added—A/B cycle only), the resistivity shows 600μΩcm; at 20% ratio of NH₃/TaSiN (1:5 ratio or 1 A/B/N cycle for every 4 A/B only cycles), the resistivity shows 3,000 μΩcm and at 50% (1:2 ratio or 1 A/B/N cycle for every 1 A/B only cycle), it became 10,000 μΩcm. Due to a good linearity as shown in the graph, the appropriate pulse ratio can be selected for the desired resistivity easily. Thus, a conductive TaSiN thin film having a resistivity between 1,000 μΩcm and 15,000 μΩcm can be selected by choice of pulse ratio.

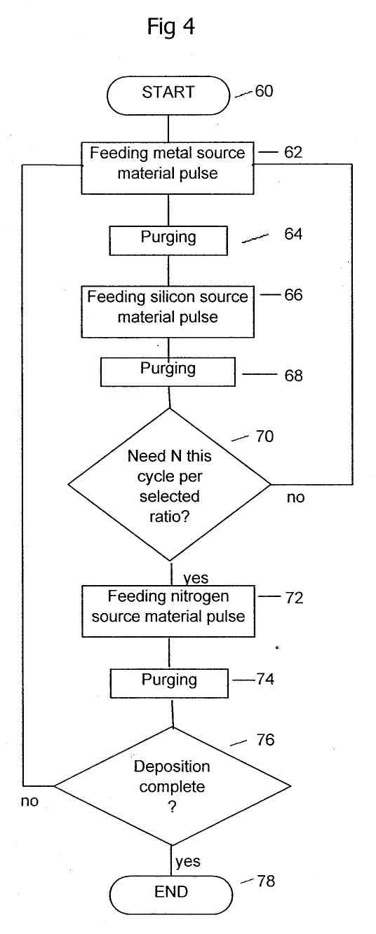

The material feeding sequence is also illustrated in the flow chart of FIG. 4. The sequence starts 60 and a metal material pulse 62 is fed to the substrate. After a purging period 64, a silicon source pulse 66 is fed to the substrate followed by a purge period 68. This constitutes an A/B cycle. Then, the need for a nitrogen source pulse 72 is assessed at decision box 70, based on the selected ratio of nitrogen source pulses to silicon/metal source pulses, which determine a resistivity of the thin film, and the recent pulsing history. If a nitrogen source pulse 72 is not necessary in this cycle, the process loops back to feeding a metal material pulse 62 and the A/B cycle is repeated. If a nitrogen source pulse 72 is desirable to satisfy the selected ratio, the nitrogen source pulse 72 is conducted, followed by a purge period 74. This would constitute the A/B/N cycle. At decision box 76 the need for another cycle is assessed based on the thickness requirement and cycles repeated if needed in the desired ratio of nitrogen to silicon and metal source pulses.

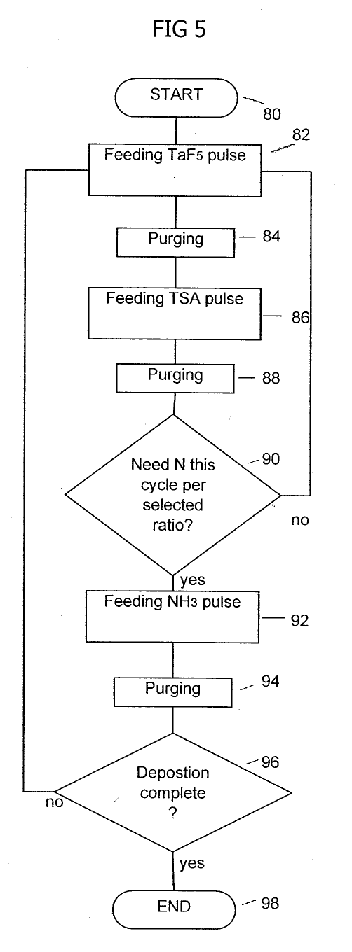

FIG. 5 illustrates a more particular embodiment employing the precursors noted above. The sequence starts 80 and a TaF₅ pulse 82 is fed to the substrate. After a purging period 84, a TSA pulse 86 is fed to the substrate followed by a purge period 88. This constitutes an A/B cycle. Then, the need for a NH₃ source pulse 92 is assessed at decision box 90, based on the selected ratio of NH₃ source pulses to TSA/TaF₅ pulses, which determine a resistivity of the thin film, and the recent pulsing history. If a NH₃ source pulse 92 is not necessary in this cycle, the process loops back to feeding a TaF₅ material pulse 82 and the A/B cycle is repeated. If a NH₃ source pulse 92 is desirable to satisfy the selected ratio, the NH₃ source pulse 92 is conducted, followed by a purge period 94. This would constitute the A/B/N cycle. At decision box 96 the need for another cycle is assessed based on the thickness requirement and cycles repeated if needed in the desired ratio of nitrogen to silicon and metal source pulses.

In one example, the thin metallic film is used as a thin metal film resistor. Accordingly the deposition is integrated into a process flow for making a resistor, such as in an integrated circuit. As noted above, for a resistor application, the thin film is typically greater than 50 nm in thickness, although for other applications the film can be much thinner due to the excellent control and conformality provided by the ALD process. Advantageously, the sheet resistance (resistivity/thickness) for the resultant thin films is extremely uniform, demonstrating less than 1% non-uniformity.

Although, the foregoing invention has been described in terms of certain embodiments, other embodiments will become apparent to those of ordinal skilled in the art in view of disclosure herein. In particular, the number of precursors can be varied. Accordingly, the present invention is not intended to be limited by the recitation of embodiments, but is intended to be defined solely by reference to the dependent claims.

What is claimed is:

1. A process for forming metal nitride thin film by atomic layer deposition (ALD,) comprising:
feeding into a reaction space vapor phase alternated pulses of metal source material and silicon source material in a plurality of cycles, and
feeding into the reaction space vapor phase pulses of nitrogen source material, wherein a nitrogen source pulse is fed intermittently in selected cycles such that a ratio of nitrogen source pulses to silicon source pulses is less than 1:1 and a ratio of nitrogen source pulses to metal source pulses is less than 1:1, wherein the deposited metal nitride thin film has a resistivity between 1,000 μΩcm and 15,000 μΩcm.

2. The process according to claim 1, wherein, in the selected cycles, feeding the nitrogen source pulse is conducted between a silicon source pulse and the next metal source pulse.

3. The process according to claim 1, wherein each pulse of metal source material and silicon source material is followed by a purging period.

4. The process according to claim 1, wherein the silicon source material is trisilylamine (TSA), the metal source material is TaF₅, and the nitrogen source material is NH₃.

5. The process according to claim 1, wherein the metal nitride thin film forms part of a thin metal film resistor.

6. The process according to claim 1, wherein a non-uniformity of sheet resistance across the metal nitride thin film is less than 1%.

7. The process according to claim 1, wherein the metal source material is selected from the group consisting of TaF₅ and NbF₅.

8. The process according to claim 7, wherein the silicon source material is selected from the group consisting of TSA, silane, silicon chloride, TMDS, TDMAS, and BDEAS.

9. A conductive TaSiN thin film having a resistivity between 1,000 μΩ·cm and 15,000 μΩ·cm.

10. The conductive TaSiN thin film of claim 9, having a thickness greater than 50 nm for a resistor application.

11. The conductive TaSiN thin film of claim 9, having a non-uniformity of sheet resistance across the film within 1%.

12. An atomic layer deposition (ALD) process of depositing a conductive TaSiN film, the ALD process comprising
a plurality of cycles including:
supplying a pulse of TaF₅ to a reaction space housing a substrate, and
supplying a pulse of trisilylamine (TSA) to the reaction space,
the ALD process further comprising in selected cycles supplying a pulse of NH₃ between supplying the pulse of TSA and supplying the pulse of TaF₅, the pulse of NH₃ being supplied intermittently in fewer than all of the ALD cycles in a pulse ratio selected to tune resistivity of the conductive TaSiN film.

13. The ALD process according to claim 12, wherein the NH₃ pulse is supplied in a pulse ratio selected to tune the resistivity of the conductive TaSiN film to between 1,000 μΩcm and 15,000 μΩcm.

14. The ALD process according to claim 12, wherein TaSiN thin film forms part of a thin metal film resistor.
